(19) United States
(12) Patent Application Publication
(10) Pub. No.: US 2024/0355808 A1
(43) Pub. Date: Oct. 24, 2024

(54) SEMICONDUCTOR DEVICE

(71) Applicant: DB HiTek Co., Ltd., Seoul (KR)

(72) Inventors: Jong Min KIM, Seoul (KR); Young Sang SON, Bucheon-si Gyeonggi-do (KR); Young Chul KIM, Bucheon-si Gyeonggi-do (KR)

(73) Assignee: DB HiTek Co., Ltd., Seoul (KR)

(21) Appl. No.: 18/206,822

(22) Filed: Jun. 7, 2023

(30) Foreign Application Priority Data
Apr. 18, 2023 (KR) 10-2023-0046701

(51) Int. Cl. H01L 27/02

(52) U.S. Cl. CPC H01L 27/0259

(57) ABSTRACT

A semiconductor device is provided. The semiconductor device includes a substrate including a first region and a second region surrounding the first region, a collector extending in a first direction in the first region of the substrate, an emitter that is spaced apart from the collector in a second direction and extends in the first direction, in the first region of the substrate, a floating region that is disposed between the collector and the emitter and extends in the first direction, in the first region of the substrate, a first device separation region between the floating region and the collector in the first region of the substrate, a second device separation region between the floating region and the emitter in the first region of the substrate and a base disposed in the second region of the substrate, wherein the floating region is not connected to an element including a conductor.

### CROSS REFERENCE TO RELATED APPLICATION

This application claims priority to Korean Patent Application No. 10-2023-0046701 filed on Apr. 18, 2023, the entire contents of which are herein incorporated by reference.

### TECHNICAL FIELD

The disclosure relates to a semiconductor device.

### BACKGROUND

The statements in this section merely provide background information related to the disclosure and may not constitute prior art.

A high-voltage electrostatic discharge (ESD) protection device is required to protect a semiconductor device from static electricity. A bipolar junction transistor (BJT) may be used as an ESD protection device.

In a semiconductor device used as the ESD protection device, resistance of the semiconductor device may be weakened due to a phenomenon in which a hole current is concentrated between an emitter and a collector.

In addition, a base current of the semiconductor device used as the ESD protection device flows from an n-type well of a lower portion of the emitter to an n-type well of a base, and in this case, generated base resistance is low, so that a turn-on voltage may be increased.

The description set forth in the background section should not be assumed to be prior art merely because it is set forth in the background section. The background section may describe aspects or embodiments of the disclosure.

### SUMMARY

An aspect of the disclosure is to provide a semiconductor device that reduces concentration of a hole current between an emitter and a collector.

Another aspect of the disclosure is to provide a semiconductor device that reduces a phenomenon in which an electric field is concentrated in a p-type well of a collector.

Another aspect of the disclosure is to provide a semiconductor device that increases base resistance.

Another aspect of the disclosure is to provide a semiconductor device that reduces a potential concentrated in a collector.

Aspects of the disclosure are not limited to the above-described aspects, and other aspects can be appreciated by those skilled in the art from the following descriptions. Further, it will be easily appreciated that the aspects of the disclosure can be practiced by features recited in the appended claims and a combination thereof.

According to some aspects of the disclosure, a semiconductor device includes a substrate including a first region and a second region surrounding the first region, a collector extending in a first direction in the first region of the substrate, an emitter that is spaced apart from the collector in a second direction crossing the first direction and extends in the first direction, in the first region of the substrate, a floating region that is disposed between the collector and the emitter and extends in the first direction, in the first region of the substrate, a first device separation region between the floating region and the collector in the first region of the substrate, a second device separation region between the floating region and the emitter in the first region of the substrate; and a base disposed in the second region of the substrate, wherein the floating region is not connected to an element including a conductor.

According to some aspects, the semiconductor device further includes a buried layer in the substrate, wherein the collector, the emitter, the floating region, the first device separation region, the second device separation region, and the base are disposed on the buried layer, and the floating region includes a first floating region, and a second floating region between the first floating region and the buried layer.

According to some aspects, the semiconductor device further includes a first well disposed to overlap the floating region, the emitter, and the base in the substrate on the buried layer and a second well, wherein the first well includes a first portion of the first well that overlaps a portion of the first device separation region, the second device separation region, the floating region, and the emitter and that is disposed between the emitter and the buried layer, in the substrate on the buried layer; and a second portion of the first well overlapping the base to be disposed between the base and the buried layer, in the substrate on the buried layer, the second well is disposed between the base and the second portion of the first well and the second well and the second floating region are spaced apart from each other.

According to some aspects, the first well further includes a third portion between the first portion and a portion of the second portion spaced apart therefrom in the first direction, and a width of the first portion is different from a width of the third portion. According to some aspects, the semiconductor device further includes a fifth well disposed between the second device separation region and the buried layer and between the emitter and the buried layer, wherein the second floating region and the fifth well are connected to each other.

According to some aspects, the semiconductor device further includes a plate disposed to be spaced apart from the collector on the collector, wherein the plate includes a first plate portion extending in the first direction between the collector and the floating region.

According to some aspects, the semiconductor device further includes a collector contact extending in a direction protruding from the collector and connected to the collector, wherein the first plate portion is spaced apart from the collector contact.

According to some aspects, the plate includes a second plate portion extending in the second direction from the first plate portion, and the second plate portion is disposed between the base and the collector.

According to some aspects, the semiconductor device further includes a buried layer in the substrate and a first well disposed to overlap the floating region, the emitter, and the base in the substrate on the buried layer, wherein the collector, the emitter, the floating region, the first device separation region, the second device separation region, the first well, and the base are disposed on the buried layer, the semiconductor device further includes a third well between the collector and the buried layer, and a fourth well that is spaced apart from the collector in the first direction and is disposed between the collector and the base, in the first region of the substrate and the third well and the fourth well are spaced apart from each other.

According to some aspects, the semiconductor device further includes a third device separation region disposed on the floating region between the first device separation region and the second device separation region.

Aspects of the disclosure are not limited to those mentioned above and other aspects and advantages of the disclosure that have not been mentioned can be understood by the following description and will be more clearly understood according to embodiments of the disclosure. In addition, it will be readily understood that the aspects and advantages of the disclosure can be realized by the means and combinations thereof set forth in the claims.

The semiconductor device of the invention may alleviate concentration of a hole current between an emitter and a collector due to a floating region between the emitter and the collector.

In addition, the semiconductor device of the disclosure may alleviate concentration of an electric field in a p-type well of a collector due to a plate connected to an electrode of the collector.

In addition, the semiconductor device of the disclosure provides may increase base resistance by including portions of n-type wells having different widths when connecting an n-type well of a lower portion of an emitter and an n-type well of a base.

In addition, the disclosure may provide a semiconductor device that may alleviate a potential concentrated on a collector by including another p-type well spaced apart from a p-type well of the collector.

In addition to what has been described, specific effects of the disclosure will be described together while describing specific details for carrying out the disclosure.

In addition to the foregoing, the specific effects of the disclosure will be described together while elucidating the specific details for carrying out the embodiments below.

### BRIEF DESCRIPTION OF THE DRAWINGS

FIG. 1 illustrates a top plan view of a semiconductor device according to some embodiments of the disclosure.

FIG. 2 illustrates a layout diagram of a semiconductor device according to some embodiments of the disclosure.

FIG. 3 illustrates a cross-sectional view taken along line A-A′ of FIG.

FIG. 4 illustrates a layout diagram of a semiconductor device according to some embodiments of the disclosure.

FIG. 5 illustrates a top plan view of a semiconductor device according to some embodiments of the disclosure.

FIG. 6 illustrates a cross-sectional view taken along line B-B′ of FIG. 5.

FIG. 7 illustrates a top plan view of a semiconductor device according to some embodiments of the disclosure.

FIG. 8 illustrates a cross-sectional view taken along line C-C′ of FIG. 7.

FIG. 9 illustrates a cross-sectional view taken along line A-A′ of FIG. 1.

FIG. 10 illustrates a top plan view of a semiconductor device according to some embodiments of the disclosure.

FIG. 11 illustrates a cross-sectional view taken along line D-D′ of FIG. 10.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “have,” etc. should be understood as not precluding the possibility of existence or addition of features, numbers, steps, operations, components, parts, or combinations thereof described herein.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

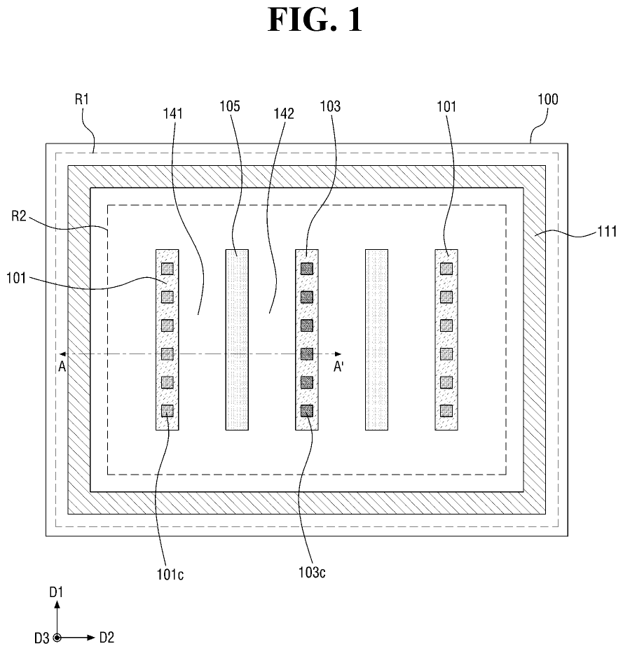

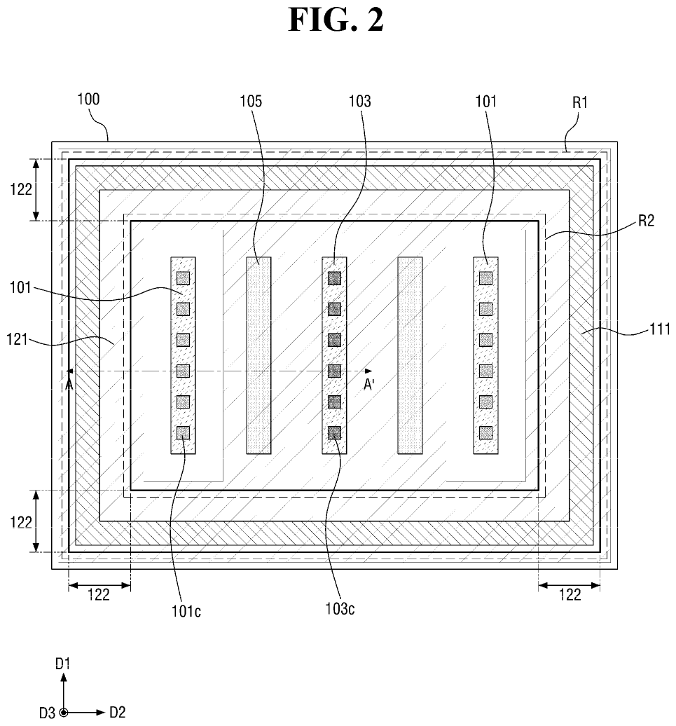

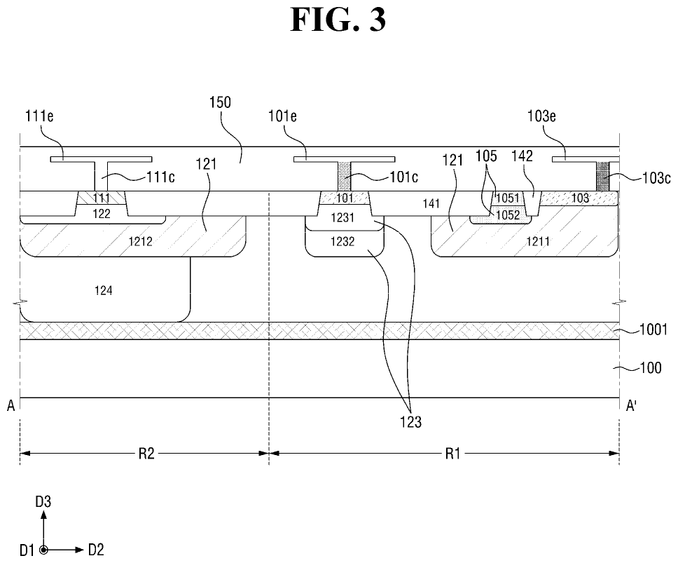

Hereinafter, a semiconductor device according to an embodiment of the disclosure will be described with reference to FIG. 1, FIG. 2, and FIG. 3.

FIG. 1 illustrates a top plan view of a semiconductor device according to some embodiments of the disclosure. In FIG. 1, for clarity of illustration, some components including electrodes and an insulating layer 150 are omitted, and a plurality of base contacts disposed on a base 111 are omitted.

FIG. 2 illustrates a layout diagram of a semiconductor device according to some embodiments of the disclosure. In FIG. 2, for clarity of illustration, some components including an insulating layer 150 and device separation regions 141 and 142 are omitted.

FIG. 3 illustrates a cross-sectional view taken along line A-A′ of FIG. 1 and FIG. 2.

Referring to FIG. 1, FIG. 2, and FIG. 3, a semiconductor device according to some embodiments of the disclosure may include a substrate 100, a collector 101, an emitter 103, a floating region 105, a base 111, a first device separation region 141, and a second device separation region 142.

The substrate 100 may include a first region R1 and a second region R2. The second region R2 may be a region of the substrate 100 surrounding the first region R1.

The substrate 100 may be, for example, bulk silicon or silicon-on-insulator (SOI). Alternatively, the substrate 100 may be a silicon substrate, or may include another material such as a silicon germanium, an indium antimonide, a lead telluride, an indium arsenide, an indium phosphide, a gallium arsenide, or a gallium antimonide. Alternatively, the substrate 100 may have an epitaxial layer formed on a base substrate.

The substrate 100 may include a buried layer 1001 within the substrate 100. The buried layer 1001 may include n-type impurities.

The collector 101 may be disposed in the first region R1 of the substrate 100. The collector 101 may be disposed on the buried layer 1001. The collector 101 may extend in a first direction D1. The collector 101 may include p-type impurities.

The emitter 103 may be disposed in the first region R1 of the substrate 100. The emitter 103 may be disposed on the buried layer 1001. The emitter 103 may extend in the first direction D1. The emitter 103 may be spaced apart from the collector 101 in a second direction D2. The second direction D2 may be a direction crossing the first direction D1. The emitter 103 may include p-type impurities.

The floating region 105 may be disposed in the first region R1 of the substrate 100. The floating region 105 may be disposed on the buried layer 1001. The floating region 105 may extend in the first direction D1. The floating region 105 may be disposed between the collector 101 and the emitter 103. The floating region 105 may be spaced apart from each of the collector 101 and the emitter 103 in the second direction D2.

The floating region 105 may include a first floating region 1051 and a second floating region 1052. The second floating region 1052 may be disposed between the first floating region 1051 and the buried layer 1001.

The floating region 105 may include n-type impurities. For example, concentrations of n-type impurities in the first floating region 1051 and the second floating region 1052 may be different from each other.

The floating region 105 may not be connected to an element including a conductor. For example, the floating region 105 may not be connected to contacts and electrodes.

The semiconductor device according to some embodiments of the disclosure includes the floating region 105 between the collector 101 and the emitter 103, so that by allowing the hole current flowing from the collector 101 to the emitter 103 to deeply flow in the substrate 100, it is possible to alleviate the concentration of current near the upper surface of the substrate 100.

A device separation film may include the first device separation region 141 and the second device separation region 142.

The first device separation region 141 may be disposed in the first region R1 of the substrate 100. The first device separation region 141 may be disposed on the buried layer 1001. The first device separation region 141 may be disposed between the collector 101 and the floating region 105. The first device separation region 141 may be disposed between the collector 101 and the floating region 105 to distinguish the collector 101 and the floating region 105.

The second device separation region 142 may be disposed in the first region R1 of the substrate 100. The second device separation region 142 may be disposed on the buried layer 1001. The second device separation region 142 may be disposed between the floating region 105 and the emitter 103. The second device separation region 142 may be disposed between the floating region 105 and the emitter 103 to distinguish the floating region 105 from the emitter 103.

The first device separation region 141 and the second device separation region 142 may include one of an oxide film, a nitride film, an oxynitride film, and a combination thereof.

The base 111 may be disposed in the first region R2 of the substrate 100. The base 111 may be disposed on the buried layer 1001. The base 111 may be disposed to surround the first region R1 in which the collector 101, the floating region 105, and the emitter 103 are disposed. The base 111 may include a portion extending in the first direction D1 and a remaining portion extending in the second direction D2. The base 111 may include n-type impurities.

A collector contact 101c may be disposed on the collector 101 to be connected to the collector 101. For example, the collector contact 101c may extend from the collector 101 in a third direction D3. The third direction D3 may be a direction crossing the first direction D1 and the second direction D2. The collector contact 101c may connect the collector 101 and a collector electrode 101e. The collector electrode 101e may be disposed on the collector contact 101c. The collector contact 101c and the collector electrode 101e may include a conductive material.

An emitter contact 103c may be disposed on the emitter 103 to be connected to the emitter 103. For example, the emitter contact 103c may extend from the emitter 103 in the third direction D3. The emitter contact 103c may connect the emitter 103 and an emitter electrode 103e. The emitter electrode 103e may be disposed on emitter contact 103c. The emitter contact 103c and the emitter electrode 103e may include a conductive material.

A base contact 111c may be disposed on the base 111 to be connected to the base 111. For example, the base contact 111c may extend from the base 111 in the third direction D3. The base contact 111c may connect the base 111 and a base electrode 111e. The base electrode 111e may be disposed on the base contact 111c. The base contact 111c and the base electrode 111e may include a conductive material.

The insulating layer 150 may be disposed on the upper surface of the substrate 100. The insulating layer 150 may be disposed on the collector 101, the emitter 103, the base 111, the first and second device separation regions 141 and 142, and the floating region 105. The insulating layer 150 may cover a portion of an upper surface of each of the collector 101, the emitter 103, and the base 111. For example, the insulating layer 150 may directly contact a portion of the upper surface of each of the collector 101, the emitter 103, and the base 111. The insulating layer 150 may cover the upper surface of each of the first and second device separation regions 141 and 142 and of the floating region 105. For example, the insulating layer 150 may directly contact the entire upper surface of each of the first and second device separation regions 141 and 142 and of the floating region 105.

As the entire upper surface of the floating region 105 directly contacts the insulating layer 150, the floating region 105 may not be connected to other elements including conductors, that is, other nodes including contacts and electrodes.

The insulating layer 150 may be disposed to cover the collector contact 101c, the collector electrode 101e, the emitter contact 103c, the emitter electrode 103e, the base contact 111c, and the base electrode 111e.

The insulating layer 150 may include an insulating material. A first well 121 may be disposed over the first region R1 and the second region R2 of the substrate 100. The first well 121 may not be disposed in one region including the collector 101 in the first region R1. For example, the first well 121 may be disposed so as not to overlap the collector 101. The first well 121 may be disposed to overlap the floating region 105, the emitter 103, and the base 111 in the substrate 100 on the buried layer 1001. For example, the first well 121 may be disposed below the emitter 103 and the base 111 while surrounding the floating region 105.

The first well 121 may include a first portion 1211 and a second portion 1212. The first portion 1211 and the second portion 1212 may be connected to each other. The first well 121 may include n-type impurities.

At least a portion of the first portion 1211 of the first well 121 may be disposed between the floating region 105 and the buried layer 1001 and between the emitter 103 and the buried layer 1001. The first portion 1211 of the first well 121 may overlap a portion of the first device separation region 141, the second device separation region 142, the floating region 105, and the emitter 103 in the third direction D3.

The second portion 1212 of the first well 121 may overlap the base 111 in the third direction D3 between the buried layer 1001 and the base 111.

A second well 122 may be disposed between the base 111 and the second portion 1212 of the first well 121. The second well 122 may be disposed between the base 111 and the second portion 1212 of the first well 121 to overlap the base 111. The second well 122 may include n-type impurities.

In some embodiments, the second well 122 may be spaced apart from the second floating region 1052. The second well 122 may be disposed so as not to overlap the floating region 105 and the emitter 103.

A third well 123 may be disposed between the collector 101 and the buried layer 1001. The third well 123 may include a first portion 1231 and a second portion 1232 of the third well 123. The first portion 1231 of the third well 123 may be disposed between the second portion 1232 of the third well 123 and the collector 101. The third well 123 may include p-type impurities. P-type impurity doping concentrations of the first portion 1231 and the second portion 1232 of the third well 123 may be different from each other.

The first portion 1231 of the third well 123 may increase an impurity concentration of the collector 101. Accordingly, a secondary trigger current may be increased by increasing a junction area of the collector 101. In addition, it is possible to lower a Ron value by reducing resistance of a current path.

A fourth well 124 may be disposed between the second portion 1212 of the first well 121 and the buried layer 1001, and may contact the buried layer 1001. The fourth well 124 may include n-type impurities. Since the fourth well 124 contacts the buried layer 1001, an area of a base region including the base 111, the second well 122, the second portion 1212 of the first well 121, and the fourth well 124 may be increased.

It has been described that a certain number of collectors 101, floating regions 105, and emitters 103 are disposed in the drawings, but the disclosure is not limited thereto. Alternatively, a larger number of collectors 101, floating regions 105, and emitters 103 may be disposed.

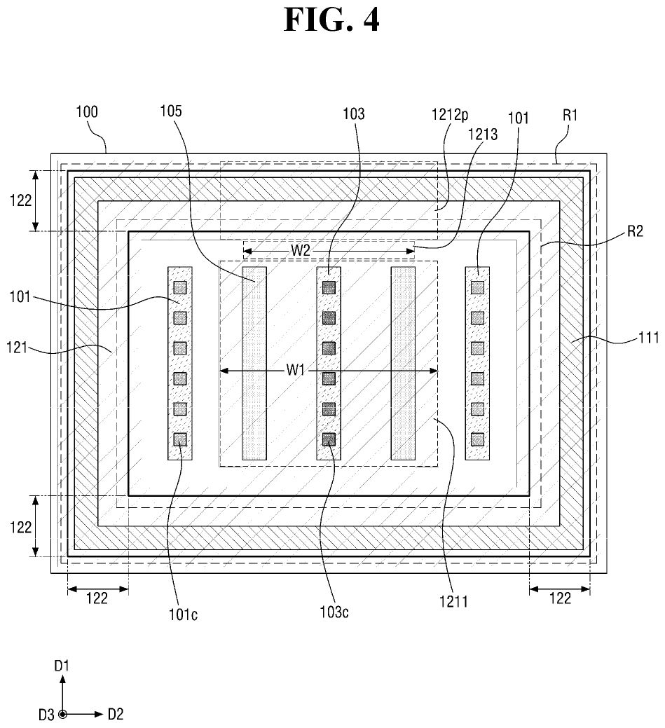

Hereinafter, a semiconductor device according to some embodiments of the disclosure will be described with reference to FIG. 1 and FIG. 4. For better understanding and ease of description, descriptions overlapping those described above will be simplified or omitted.

FIG. 4 illustrates a layout diagram of a semiconductor device according to some embodiments of the disclosure. In FIG. 4, for clarity of illustration, some components including the insulating layer and the first and second device separation regions 141 and 142 are omitted.

Referring to FIG. 1 and FIG. 4, the first well 121 of the semiconductor device according to some embodiments may further include a third portion 1213 of the first well 121.

The third portion 1213 of the first well 121 may be a portion that is spaced apart from or parallel to the first portion 1211 of the first well 121 in the first direction D1. The third portion 1213 of the first well 121 may be a portion between the first portion 1211 of the first well 121 and a portion 1212p of the second portion 1212 of the first well 121. The portion 1212p of the second portion 1212 of the first well 121 may be a portion of the second portion 1212 of the first well 121. The third portion 1213 of the first well 121 may be a portion that does not overlap the base 111, the emitter 103, and the floating region 105.

A first width W1 of the first portion 1211 of the first well 121 may be larger than a second width W2 of the third portion 1213 of the first well 121. When the semiconductor device is turned on, the base current flows from the emitter 103 to the base 111, and in this case, resistance is increased by making the second width W2 of the third portion 1213 of the first well 121 smaller than the first width W1 of the first portion 1211 of the first well 121, so that an turn-on operation between the collector 101 and the emitter 103 may become faster, and an operation of the semiconductor device may be stabilized.

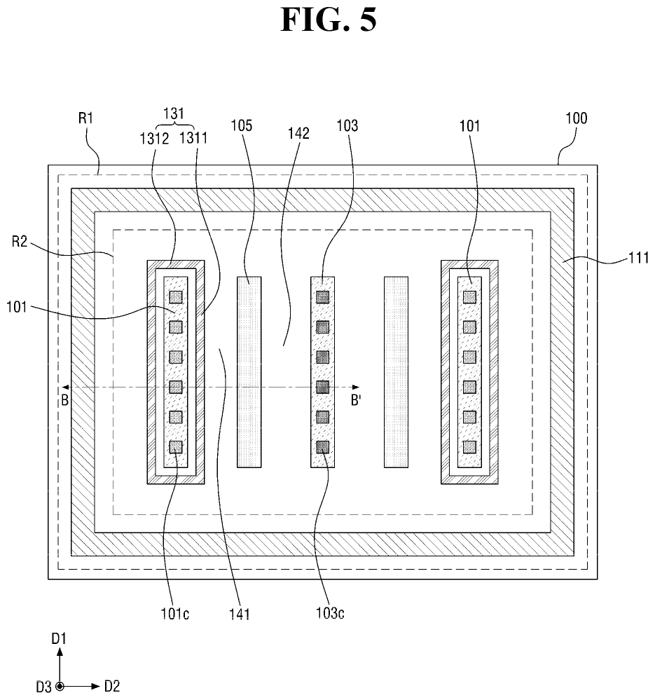

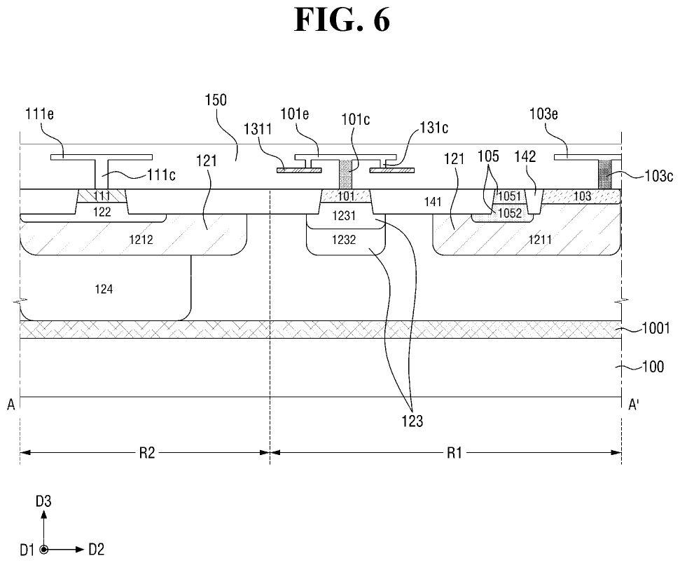

Hereinafter, a semiconductor device according to some embodiments of the disclosure will be described with reference to FIG. 5 and FIG. 6. For better understanding and ease of description, descriptions overlapping those described above will be simplified or omitted.

FIG. 5 illustrates a top plan view of a semiconductor device according to some embodiments of the disclosure. In FIG. 5, for clarity of illustration, some components including the insulating layer 150 and the electrode are omitted, and a plurality of base contacts disposed on the base 111 are omitted. FIG. 6 illustrates a cross-sectional view taken along line B-B′ of FIG. 5.

Referring to FIG. 5 and FIG. 6, a semiconductor device according to some embodiments of the disclosure may further include a plate 131.

The plate 131 may be disposed on the collector 101 to be spaced apart from the collector 101 in the third direction D3. The plate 131 may surround the collector 101. The plate 131 may be spaced apart from the collector contact 101c. For example, the plate 131 may be spaced apart from the floating region 105, and may not overlap it in the third direction D3.

The plate 131 may include a conductive material.

The plate 131 may be connected to the collector electrode 101e by a connection portion 131c. The connection portion 131c may include a conductor.

The plate 131 may include a first plate portion 1311 and a second plate portion 1312. The first plate portion 1311 may extend in the first direction D1 between the collector 101 and the floating region 105. The first plate portion 1311 and the second plate portion 1312 may be spaced apart from the collector contact 101c. The second plate portion 1312 may extend in the second direction D2 between the collector 101 and the base 111. The second plate portion 1312 may extend from the first plate portion 1311 in the second direction D2. The first plate portion 1311 and the second plate portion 1312 may be connected to each other.

The semiconductor device according to some embodiments of the disclosure includes the plate 131, so that the plate 131 pushes the potential distribution from the collector 101 to the emitter 103, thereby reducing a phenomenon in which the electric field is concentrated near the collector 101.

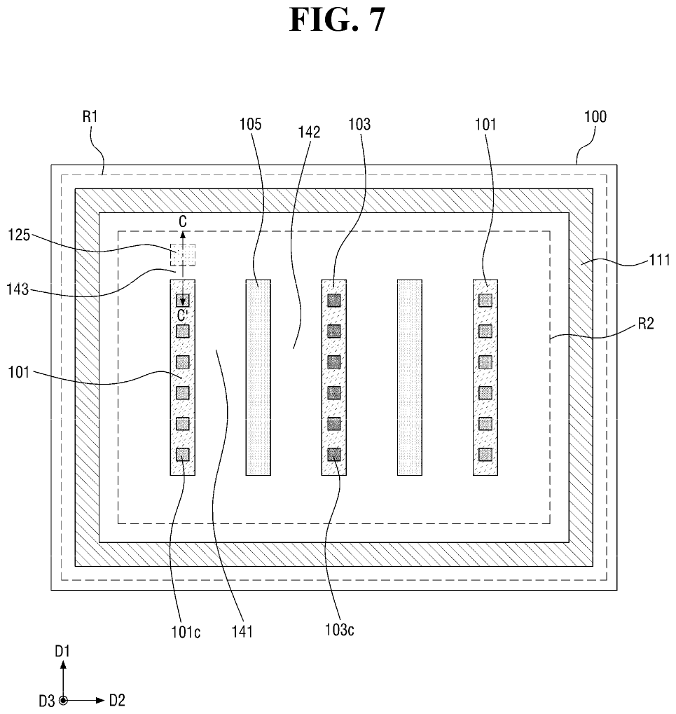

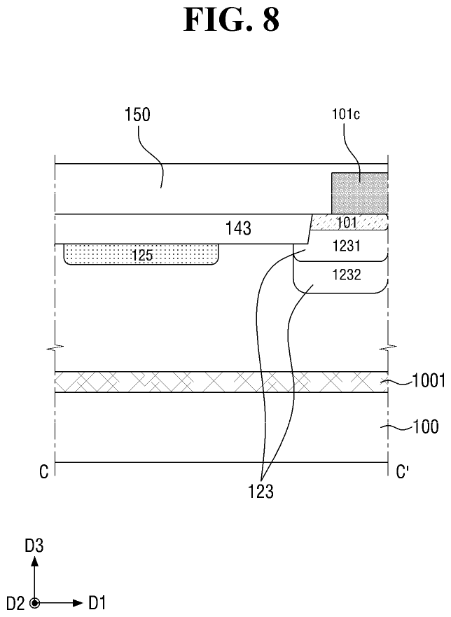

Hereinafter, a semiconductor device according to some embodiments of the disclosure will be described with reference to FIG. 7 and FIG. 8. For better understanding and ease of description, descriptions overlapping those described above will be simplified or omitted.

FIG. 7 illustrates a top plan view of a semiconductor device according to some embodiments of the disclosure. In FIG. 7, for clarity of illustration, some components including the insulating layer 150 and the electrode are omitted, and a plurality of base contacts disposed on the base 111 are omitted. FIG. 8 illustrates a cross-sectional view taken along line C-C′ of FIG. 7.

Referring to FIG. 7 and FIG. 8, a semiconductor device according to some embodiments of the disclosure may further include a fifth well 125.

The fifth well 125 may be spaced apart from the collector 101 in the first direction D1 in the first region R1 of the substrate 100, and may be disposed between the collector 101 and the base 111. The fifth well 125 may be spaced apart from the collector 101 and the third well 123 in the first direction D1. The fifth well 125 may include p-type impurities.

A third device separation region 143, which is a partial region of the device separation film, may be a portion of a separation region including the first device separation region 141 and the second device separation region 142 that are parallel to the collector 101 in the first direction D1. The fifth well 125 may be disposed below the third device separation region 143. The fifth well 125 may be disposed between the third device separation region 143 and the buried layer 1001.

The semiconductor device according to some embodiments of the disclosure may reduce a potential concentrated on the collector 101 by further including the fifth well 125.

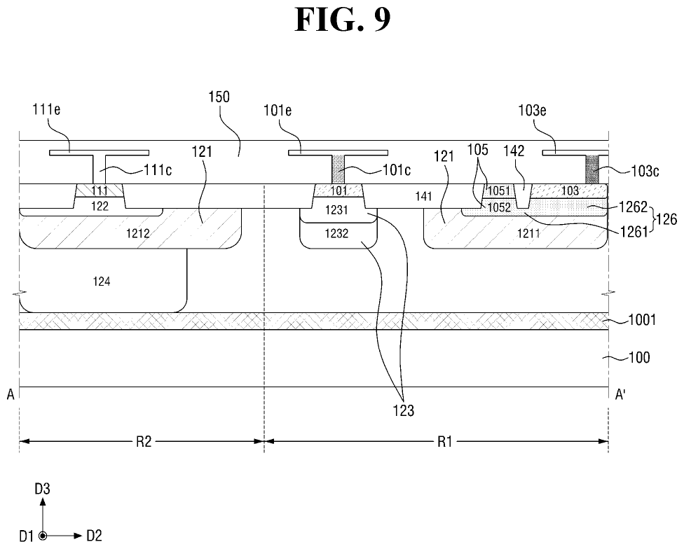

Hereinafter, a semiconductor device according to some embodiments of the disclosure will be described with reference to FIG. 1 and FIG. 9. For better understanding and ease of description, descriptions overlapping those described above will be simplified or omitted.

FIG. 9 illustrates a cross-sectional view taken along line A-A′ of FIG. 1.

Referring to FIG. 1 and FIG. 9, a semiconductor device according to some embodiments of the disclosure may further include a sixth well 126.

The sixth well 126 may include a first portion 1261 and a second portion 1262 of the sixth well 126. The first portion 1261 of the sixth well 126 may be disposed between the first portion 1211 of the first well 121 and the second device separation region 142. The second portion 1262 of the sixth well 126 may be disposed between the first portion 1211 of the first well 121 and the emitter 103. The first portion 1261 of the sixth well 126 may be disposed between the second floating region 1052 and the second portion 1262 of the sixth well 126. The second floating region 1052, the first portion 1261 of the sixth well 126, and the second portion 1262 of the sixth well 126 may be connected to each other.

The sixth well 126 may include n-type impurities. The n-type impurity doping concentration of the sixth well 126 may be higher than that of the first portion 1211 of the first well 121.

The semiconductor device according to some embodiments of the disclosure further includes the sixth well 126 extending from the second floating region 1052 in the second direction D2 below the emitter 103, so that the doping concentration of the n-type wells 126 and 1211 may be increased to increase the holding voltage of the semiconductor device, thus it is possible to implement a high-voltage electrostatic discharge protection device.

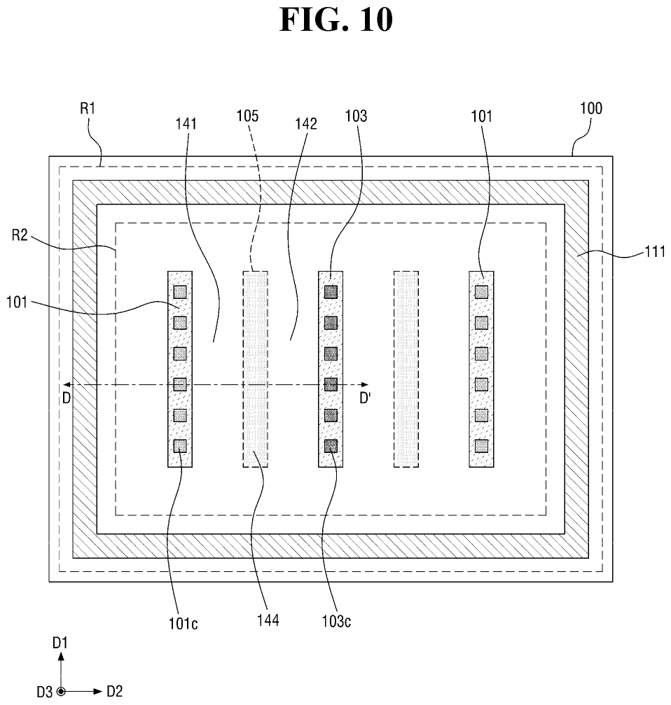

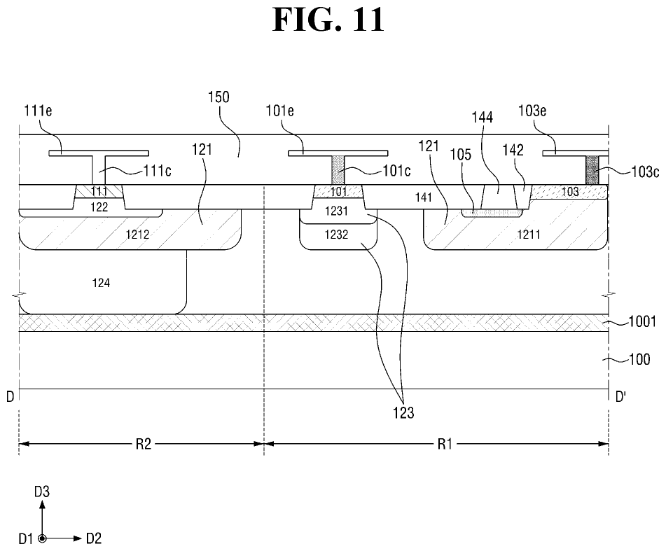

Hereinafter, a semiconductor device according to some embodiments of the disclosure will be described with reference to FIG. 10 and FIG. 11. For better understanding and ease of description, descriptions overlapping those described above will be simplified or omitted.

FIG. 10 illustrates a top plan view of a semiconductor device according to some embodiments of the disclosure. In FIG. 10, for clarity of illustration, some components including the insulating layer 150 and the electrode are omitted, and a plurality of base contacts disposed on the base 111 are omitted. FIG. 11 illustrates a cross-sectional view taken along line D-D′ of FIG. 10.

Referring to FIG. 10 and FIG. 11, a semiconductor device according to some embodiments may further include a fourth device separation region 144 on the floating region 105.

Unlike shown in FIG. 1, the floating region 105 may include only the second floating region 1052. The floating region 105 may be disposed between the collector 101 and the emitter 103. The fourth device separation region 144, which is a partial region of the device separation film, may be disposed on the floating region 105. The fourth device separation region 144 may be disposed between the first device separation region 141 and the second device separation region 142. The first device separation region 141, the fourth device separation region 144, and the second device separation region 142 may be connected to each other. The fourth device separation region 144 may be a partial region of the device separation region including the first device separation region 141 and the second device separation region 142.

The semiconductor device according to some embodiments of the disclosure further includes the floating region 105 below the fourth device separation region 144 so that it is possible to reduce a phenomenon in which a hole current is concentrated between the collector 101 and the emitter 103.

The foregoing description is merely illustrative of the technical spirit of the embodiment. It will be appreciated by those skilled in the art that various modifications and alterations can be made without departing from the essential characteristics of the embodiment. Therefore, the embodiments of the disclosure have not been described for limiting purposes, and the scope of the spirit of the disclosure is not limited by these embodiments. The protection range of the embodiment should be construed by the claims below, and all technical ideas within an equivalent range thought should be construed as being included within the scope of the embodiment.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor device comprising:
a substrate including a first region and a second region surrounding the first region;
a collector extending in a first direction in the first region of the substrate;
an emitter that is spaced apart from the collector in a second direction crossing the first direction and extends in the first direction, in the first region of the substrate;
a floating region that is disposed between the collector and the emitter and extends in the first direction, in the first region of the substrate;
a first device separation region between the floating region and the collector in the first region of the substrate;
a second device separation region between the floating region and the emitter in the first region of the substrate; and
a base disposed in the second region of the substrate,
wherein the floating region is not connected to an element including a conductor.

2. The semiconductor device of claim 1, further comprising
a buried layer in the substrate,
wherein the collector, the emitter, the floating region, the first device separation region, the second device separation region, and the base are disposed on the buried layer, and
the floating region includes a first floating region, and a second floating region between the first floating region and the buried layer.

3. The semiconductor device of claim 2, further comprising
a first well disposed to overlap the floating region, the emitter, and the base in the substrate on the buried layer; and
a second well,
wherein the first well includes a first portion of the first well that overlaps a portion of the first device separation region, the second device separation region, the floating region, and the emitter and that is disposed between the emitter and the buried layer, in the substrate on the buried layer; and a second portion of the first well overlapping the base to be disposed between the base and the buried layer, in the substrate on the buried layer;
the second well is disposed between the base and the second portion of the first well; and
the second well and the second floating region are spaced apart from each other.

4. The semiconductor device of claim 3, wherein
the first well further includes a third portion between the first portion and a portion of the second portion spaced apart therefrom in the first direction, and a width of the first portion is different from a width of the third portion.

5. The semiconductor device of claim 2, further comprising
a fifth well disposed between the second device separation region and the buried layer and between the emitter and the buried layer,
wherein the second floating region and the fifth well are connected to each other.

6. The semiconductor device of claim 1, further comprising
a plate disposed to be spaced apart from the collector on the collector,
wherein the plate includes a first plate portion extending in the first direction between the collector and the floating region.

7. The semiconductor device of claim 6, further comprising
a collector contact extending in a direction protruding from the collector and connected to the collector,
wherein the first plate portion is spaced apart from the collector contact.

8. The semiconductor device of claim 6, wherein
the plate includes a second plate portion extending in the second direction from the first plate portion, and
the second plate portion is disposed between the base and the collector.

9. The semiconductor device of claim 1, further comprising:
a buried layer in the substrate; and
a first well disposed to overlap the floating region, the emitter, and the base in the substrate on the buried layer,
wherein the collector, the emitter, the floating region, the first device separation region, the second device separation region, the first well, and the base are disposed on the buried layer;
the semiconductor device further includes a third well between the collector and the buried layer, and a fourth well that is spaced apart from the collector in the first direction and is disposed between the collector and the base, in the first region of the substrate; and
the third well and the fourth well are spaced apart from each other.

10. The semiconductor device of claim 1, further comprising
a third device separation region disposed on the floating region between the first device separation region and the second device separation region.
